(19) United States
(12) Patent Application Publication
(10) Pub. No.: US 2025/0393412 A1
(43) Pub. Date: Dec. 25, 2025

(54) DISPLAY DEVICE

(71) Applicant: Samsung Display Co., LTD., Yongin-si (KR)

(72) Inventor: Keun Woo KIM, Yongin-si (KR)

(21) Appl. No.: 19/041,200

(22) Filed: Jan. 30, 2025

(30) Foreign Application Priority Data
Jun. 25, 2024 (KR) 10-2024-0083189
Jun. 26, 2024 (KR) 10-2024-0083568

(51) Int. Cl. H10K 59/123; H10K 59/121; H10K 77/10; H10K 102/00

(52) U.S. Cl. CPC H10K 59/123; H10K 59/1213; H10K 77/111; H10K 2102/311

(57) ABSTRACT

A display device includes a first substrate, a first circuit part disposed on a front surface of the first substrate, a first light emitting part electrically connected to the first circuit part, a second substrate overlapping the first substrate and disposed on a rear surface of the first substrate, a second circuit part disposed on a rear surface of the second substrate, a second light emitting part electrically connected to the second circuit part, a printed circuit board electrically connected to the first circuit part and the second circuit part, and a driving integrated circuit chip disposed on the printed circuit board.

This application claims priority to and the benefit of Korean Patent Application No. 10-2024-0083568 filed at the Korean Intellectual Property Office on Jun. 26, 2024, and Korean Patent Application No. 10-2024-0083189 filed at the Korean Intellectual Property Office on Jun. 25, 2024, the entire contents of which are incorporated herein by reference.

### BACKGROUND

### (a) Field

The disclosure relates to a display device.

### (b) Description of the Related Art

A display device includes pixels and may display an image on a display screen by controlling the brightness of each pixel. The display device may include a touch sensing unit capable of sensing a user's touch. The display device may include a display panel having pixels disposed thereon. A touch sensing unit may be provided on a display panel. For example, the display panel may include the touch sensing unit, or a panel including the touch sensing unit may be attached to the display panel.

### SUMMARY

Embodiments of the disclosure provide a foldable display device that may be implemented in various forms.

A display device according to an embodiment includes a first substrate, a first circuit part disposed on a front surface of the first substrate, a first light emitting part electrically connected to the first circuit part, a second substrate overlapping the first substrate and disposed on a rear surface of the first substrate, a second circuit part disposed on a rear surface of the second substrate, a second light emitting part electrically connected to the second circuit part, a printed circuit board electrically connected to the first circuit part and the second circuit part, and a driving integrated circuit chip disposed on the printed circuit board.

In an embodiment, the display device may further include a first driver disposed on the first substrate, and a second driver disposed on the second substrate, where the first driver may be electrically connected to a first end of the printed circuit board, and the second driver may be electrically connected to a second end of the printed circuit board.

In an embodiment, the display device may include a first display area including the first circuit part and the first light emitting part, and the first display area may be foldable based on a folding axis extending along a predetermined direction.

In an embodiment, the display device may be in-folded based on the folding axis, and a second display area including the second circuit part and the second light emitting part may be disposed outward when the display device is in an in-folded state.

In an embodiment, a size of the second display area may be smaller than a size of the first display area.

In an embodiment, the first circuit part may include an oxide semiconductor.

In an embodiment, the second circuit part may include an oxide semiconductor.

In an embodiment, the second circuit part may include a plurality of transistors, at least one of the plurality of transistors may include an oxide semiconductor, and the remainder of the plurality of transistors may include a polycrystalline semiconductor.

In an embodiment, the first driver may include an oxide semiconductor.

In an embodiment, the second driver may include an oxide semiconductor and a polycrystalline semiconductor.

In an embodiment, a first groove may be defined on the rear surface of the first substrate, a second groove may be defined on a front surface of the second substrate to overlap the first groove, and the display device may further include a coupling member disposed in the first groove and the second groove.

In an embodiment, the coupling member may include a same material as at least one selected from the first substrate and the second substrate.

In an embodiment, the display device may further include an insulating layer disposed between the first substrate and the second substrate.

A display device according to an embodiment includes a first substrate, a first circuit part disposed on a front surface of the first substrate, a first light emitting part electrically connected to the first circuit part, a second substrate overlapping the first substrate and disposed on a rear surface of the first substrate, a second circuit part disposed on a rear surface of the second substrate, a second light emitting part electrically connected to the second circuit part, a printed circuit board electrically connected to the first circuit part and the second circuit part, and a driving integrated circuit chip disposed on the printed circuit board, wherein the first circuit part and the first light emitting part define a first display area, the second circuit part and the second light emitting part define a second display area, and the first display area is foldable.

In an embodiment, a first end of the printed circuit board may be electrically connected to the first circuit part, and a second end of the printed circuit board may be electrically connected to the second circuit part.

In an embodiment, the first circuit part may include an oxide semiconductor.

In an embodiment, the second circuit part may include a plurality of transistors, at least one of the plurality of transistors may include an oxide semiconductor, and the remainder of the plurality of transistors may include a polycrystalline semiconductor.

In an embodiment, a first groove may be defined on the rear surface of the first substrate, t a second groove may be defined on the front surface of the second substrate to overlap the first groove, and the display device may further include a coupling member disposed in the first groove and the second groove.

In an embodiment, the coupling member may include a same material as at least one selected from the first substrate and the second substrate.

In an embodiment, the coupling member may include polyimide.

According to embodiments, it is possible to provide foldable display devices having various shapes.

### BRIEF DESCRIPTION OF THE DRAWINGS

FIG. 1 is a perspective view of a display device according to an embodiment.

FIG. 2 is a perspective view of a display device in a folded state according to an embodiment.

FIG. 3 is a perspective view of a display device in a partially folded state according to an embodiment.

FIG. 4 is a cross-sectional view taken along some areas of a display device according to an embodiment.

FIG. 5 is an exploded perspective view of a display device according to an embodiment.

FIG. 6 is a cross-sectional view of some areas of a substrate according to an embodiment.

FIG. 7 is a schematic cross-sectional view of a pixel according to an embodiment.

FIG. 8 is a circuit diagram of a pixel according to an embodiment.

FIG. 9 is a circuit diagram of a pixel according to an embodiment.

FIG. 10 is a block diagram of an electronic device according to an embodiment.

FIG. 11 shows schematic diagrams of electronic devices according to various embodiments.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

In addition, the phrase “on a plane” or “in a plan view” means a view from a position above the object (e.g., from the top), and the phrase “in a cross-section” means a view of a cross-section of the object which is vertically cut from the side.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

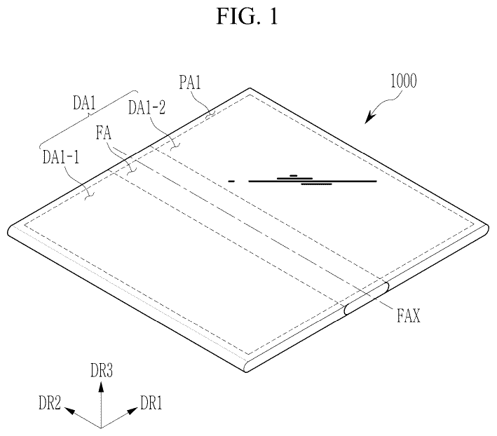

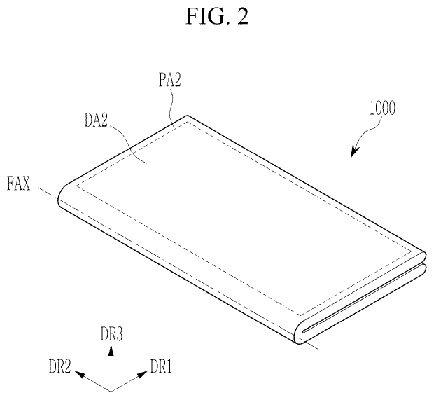

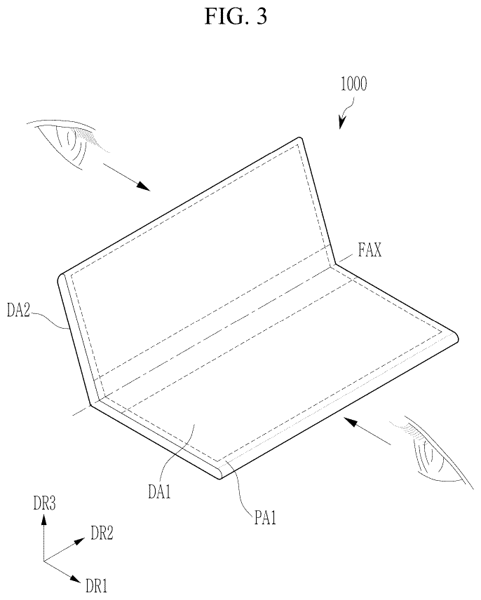

Hereinafter, a display device according to an embodiment will be described with reference to FIGS. 1 to 3. FIG. 1 is a perspective view of a display device according to an embodiment, FIG. 2 is a perspective view of a display device in a folded state according to an embodiment, and FIG. 3 is a perspective view of a display device in a partially folded state according to an embodiment.

Referring to FIG. 1, a display device 1000 according to an embodiment represents a device for displaying videos or still images, and it may be included in (e.g., used as a display screen for) portable electronic devices such as mobile phones, smartphones, tablet personal computers (PC), mobile communication terminals, electronic organizers, electronic books, portable multimedia players (PMP), global positioning systems, or ultramobile PCs (UMPC), and also for various products such as televisions, laptops, monitors, advertisement boards, or the Internet of Things (IOT). In addition, the display device 1000 according to an embodiment may be included in or used as a dashboard of a vehicle, a center information display (CID) disposed on a center fascia or a dashboard of a vehicle, a room mirror display replacing a side-view mirror of a vehicle, and a display disposed on a rear surface of a front seat for entertainment in a back seat of a vehicle. For convenience of description, FIG. 1 illustrates an embodiment where the display device 1000 is used as a smart phone.

The display device 1000 may display images in a third direction DR3 from a displaying surface on a plane defined by a first direction DR1 and a second direction DR2. The displaying surface for displaying images may correspond to a front surface of the display device 1000. The images may include videos and still images.

In an embodiment, front surfaces (or upper surfaces) and rear surfaces (or lower surfaces) of each member are defined with reference to the direction in which the image is displayed. The front surface and the rear surface may oppose each other in a third direction DR3, and normal-line directions of the front surface and the rear surface may be parallel to the third direction DR3. A separation distance between the front surface and the rear surface in the third direction DR3 may correspond to a thickness of a display panel DP in the third direction DR3, that is, the third direction DR3 may be a thickness direction of the display panel DP.

The display device 1000 according to an embodiment may sense user input applied from the outside. The user input may include various types of external inputs such as some of the human body of the user, light, heat, or pressure.

In an embodiment, the display device 1000 may be a foldable display device. The display device 1000 may be folded outward or inward with reference to a folding axis FAX extending along the second direction DR2. When the display device 1000 is folded outward with reference to the folding axis FAX, the display surfaces of the display device 1000 are disposed on the outside in the third direction DR3 so that images may be displayed in both directions.

In an embodiment, the display device 1000 may include a first display area DA1 and a first non-display area PA1. The first display area DA1 may be divided into a first non-folding display area DA1-1, a second non-folding display area DA1-2, and a folding area FA. The first non-display area PA1 may be an area surrounding the first display area DA1.

The first non-folding display area DA1-1 and the display area DA1-2 may be disposed on the left and right sides, respectively, with reference to (or centered on) the folding axis FAX, and the folding area FA may be disposed between the first non-folding display area DA1-1 and the second non-folding display area DA1-2. In such an embodiment, when folded outward with reference to the folding axis FAX, the first non-folding display area DA1-1 and the second non-folding display area DA1-2 are disposed to face both opposing sides in the third direction DR3, respectively, and the image may be displayed in both opposing directions in the third direction DR3. In an embodiment, when folded inward with reference to the folding axis FAX, the first non-folding display area DA1-1 and the second non-folding display area DA1-2 may not be visible from the outside.

Referring to FIG. 2, a display device 1000 according to an embodiment may be folded inward based on a folding axis FAX. In such a folded state, the display device 1000 may be reduced in length along the first direction DR1 by about a half.

The display device 1000 folded inward based on the folding axis FAX may include a second display area DA2 and a second non-display area PA2. The display device 1000 may include the second display area DA2 when folded inward based on the folding axis FAX. The second non-display area PA2 may surround the second display area DA2.

The second display area DA2 may be disposed on the rear surface of the first display area DA1. The length in the first direction DR1 of the second display area DA2 may be close to half the length in the first direction DR1 of the first display area DA1. The length in the second direction DR2 of the second display area DA2 may be substantially the same as the length in the second direction DR2 of the first display area DA1.

Referring to FIG. 3, in an embodiment, the display device 1000 may be a foldable device. In the disclosure, a foldable device is a device that may be folded, and is used to include not only a folded device, but also a device that may have both a folded state and an unfolded state. In addition, folding typically includes, but is not limited to, folding at an angle of about 180°, and may also be understood as being folded when a folding angle exceeds 180° or does not reach 180°—for example, when bent at an angle of more than 90° but less than 180°, or more than 120° but less than 180°. In addition, the folded state may be referred to as a folded state when it is in a bent state beyond the unfolded state, even if it is not fully folded. For example, even if the display device 1000 is bent at an angle of 90° or less, it may be expressed as being in a folded state to distinguish it from an unfolded state as long as the maximum folding angle is 90° or more. The radius of curvature when it is folded may be about 5 millimeters (mm) or less, e.g., in a range of about 1 mm to about 2 mm, or about 1.5 mm, but is not limited thereto.

As shown in FIG. 3, the display device 1000 according to an embodiment may have a partially folded state based on the folding axis FAX parallel to the second direction DR2. Each of the first display area DA1 and the second display area DA2 may display an image. That is, each of the first display area DA1 and the second display area DA2 displays images in both directions, such that users facing each other may see each screen. In embodiments, a part of the first display area DA1 may be used as an input means such as a keyboard. Power consumption may be reduced by operating at low power, such as in an input means, at least in a part of the first display area DA1.

The display device 1000 may display an image through the first display area DA1 in a fully unfolded state as shown in FIG. 1, display an image through the second display area DA2 in a fully folded state as shown in FIG. 2, or display an image through the first display area DA1 and the second display area DA2 in a partially folded state as shown in FIG. 3.

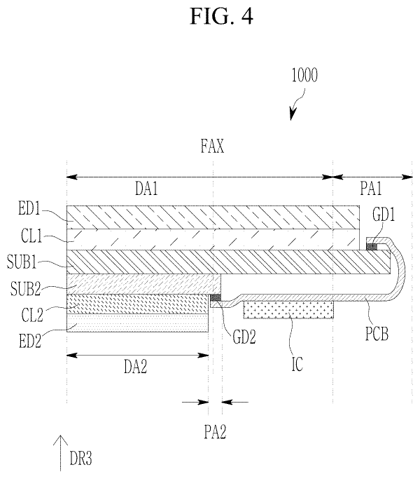

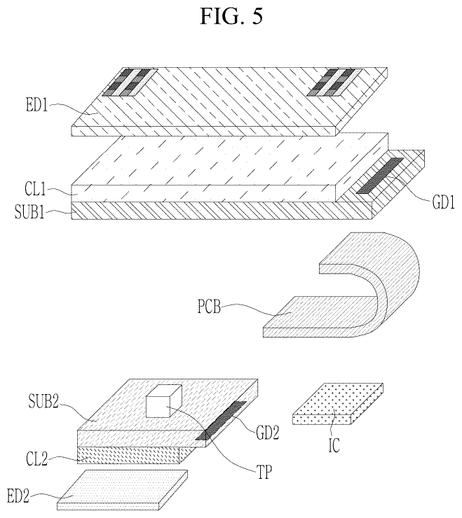

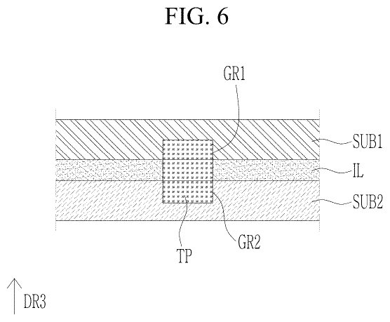

Hereinafter, a display device according to an embodiment will be described in reference to FIGS. 4 to 6. FIG. 4 is a cross-sectional view taken along some areas of a display device according to an embodiment, FIG. 5 is an exploded perspective view of a display device according to an embodiment, and FIG. 6 is a cross-sectional view of some areas of a substrate according to an embodiment.

Referring to FIGS. 4 and 5, the display device 1000 according to an embodiment includes a first substrate SUB1 and a second substrate SUB2 that overlap each other. The second substrate SUB2 may be disposed on the rear surface of the first substrate SUB1.

In an embodiment, a first circuit part CL1 and a first light emitting part ED1 may be disposed on the first substrate SUB1 sequentially in the third direction DR3. In an embodiment, a second circuit part CL2 and a second light emitting part ED2 may be disposed on the second substrate SUB2 sequentially in a direction opposite to the third direction DR3.

Each of the first substrate SUB1 and the second substrate SUB2 is a flexible substrate and may include a film substrate including a polymer organic material or a plastic substrate. In an embodiment, for example, each of the first substrate SUB1 and the second substrate SUB2 may independently include at least one selected from polyethersulfone (PES), polyacrylate, polyetherimide (PEI), polyethylene naphthalate (PEN), polyethylene terephthalate (PET), polyphenylene sulfide (PPS), polyarylate (PAR), polyimide (PI), polycarbonate (PC), triacetate cellulose (TAC), and cellulose acetate propionate (CAP).

The first substrate SUB1 may have a size (or a planar area) corresponding to the width of the first display area DA1 and the first non-display area PA1. The second substrate SUB2 may have a size corresponding to the width of the second display area DA2 and the second non-display area PA2. The size of the second substrate SUB2 may be close to half the size of the first substrate SUB1.

The first circuit part CL1 may be disposed on a surface of the first substrate SUB1. The second circuit part CL2 may be disposed on a surface of the second substrate SUB2. In an embodiment, the first substrate SUB1 and the second substrate SUB2 may be interposed between the first circuit part CL1 and the second circuit part CL2. The first circuit part CL1 and the second circuit part CL2 may overlap each other in the third direction DR3.

Signal lines such as a gate line, a data line, and a driving voltage line may be disposed in each of the first circuit part CL1 and the second circuit part CL2. Each pixel may be connected to a gate line, a data line, a driving voltage line, etc., and receive a gate signal, a data voltage, a driving voltage, etc. from among these signal lines.

Each of the first circuit part CL1 and the second circuit part CL2 may include a transistor. In embodiments, the first circuit part CL1 may include oxide transistors, and the second circuit part CL2 may also include oxide transistors. Alternatively, the first circuit part CL1 may include oxide transistors, and the second circuit part CL2 may include a combination of oxide transistors and polycrystalline transistors. Oxide transistors and polycrystalline transistors will be described later.

The first light emitting part ED1 may be disposed on the first circuit part CL1. The first light emitting part ED1 may be electrically connected to the first circuit part CL1. The second light emitting part ED2 may be disposed on the second circuit part CL2. The second light emitting part ED2 may be electrically connected to the second circuit part CL2.

Each of the first light emitting part ED1 and the second light emitting part ED2 may include a plurality of light emitting devices. The light emitting device may include a first electrode, a light emitting layer, and a second electrode, and the detailed structure thereof will be described below.

The display device 1000 according to an embodiment may include a printed circuit board (PCB) electrically connected to the first circuit part CL1 and the second circuit part CL2. The PCB may be at least partially flexible and capable of bending. The PCB may be referred to as a flexible printed circuit board or a printed circuit film.

A driving device that generates and/or processes various signals for driving the display device 1000 may be disposed in the first non-display area PA1 and the second non-display area PA2. According to an embodiment, a first driver GD1 electrically connected to the first circuit part CL1 may be disposed on the first substrate SUB1, and a second driver GD2 electrically connected to the second circuit part CL2 may be disposed on the second substrate SUB2.

The driving device may include a data driver that applies a data voltage to data lines, a gate driver that applies a gate signal to gate lines, and a signal controller that controls the data driver and the gate driver. Pixels may receive data voltage at a predetermined timing according to the gate signal generated by the gate driver. In an embodiment, each of the first driver GD1 and the second driver GD2 according to the embodiment may be a gate driver. Each of the first driver GD1 and the second driver GD2 may be integrated on the substrates SUB1 and SUB2 and disposed on at least one side of the non-display areas PA1 and PA2.

The data driver may be provided as a driving integrated circuit chip IC. The driving integrated circuit chip IC may be disposed on the PCB. One end of the PCB may be electrically connected to the first driver GD1 disposed in the first non-display area PA1, and another end of the PCB may be electrically connected to the second driver GD2 disposed in the second non-display area PA2. The PCB may have a bent shape to be connected to the first non-display area PA1 and the second non-display area PA2. The driving integrated circuit chip IC may be disposed on a flat portion of a bent PCB. The driving integrated circuit chip IC may overlap the first display area DA1 in cross-section or in the third direction DR3.

The driving integrated circuit chip IC may have a three-dimensional shape of an approximately rectangular parallelepiped and a planar shape of an approximately rectangular shape. The data driver may be provided as one or more driving integrated circuit chips ICs depending on the size of the display device 1000. In an embodiment, the signal controller may be integrated into the driving integrated circuit chip IC.

Referring to FIG. 5 and FIG. 6, the first substrate SUB1 and the second substrate SUB2 according to an embodiment may be coupled (or attached) to each other through a coupling member TP. As shown in FIG. 6, the first substrate SUB1 may include a first groove GR1 recessed in the third direction DR3 (or toward the second substrate SUB2). The second substrate SUB2 may include a second groove GR2 recessed in the direction opposite to the third direction DR3 (or toward the first substrate SUB1). The first groove GR1 and the second groove GR2 may overlap in the third direction DR3 and face each other.

In an embodiment, as shown in FIG. 6, the first groove GR1 and the second groove GR2 may be defined partially through the first and second substrates SUB1 and SUB2 in the thickness direction DR3, but is not limited thereto. In another embodiment, the first groove GR1 and the second groove GR2 may be defined or formed completely through the first substrate SUB1 and the second substrate SUB2, respectively, as through holes.

The coupling member TP may be disposed within the first groove GR1 and the second groove GR2. The coupling member TP may fill the first groove GR1 and the second groove GR2. The first substrate SUB1 and the second substrate SUB2 may be coupled to each other by the coupling member TP.

In an embodiment, the coupling member TP may include at least one selected from polyethersulfone (PES), polyacrylate, polyetherimide (PEI), polyethylene naphthalate (PEN), polyethylene terephthalate (PET), polyphenylene sulfide (PPS), polyarylate (PAR), polyimide (PI), polycarbonate (PC), triacetate cellulose (TAC), and cellulose acetate propionate (CAP) s. The coupling member TP may include a same material as at least one selected from the first substrate SUB1 and the second substrate SUB2.

In an embodiment, as shown in FIG. 6, an insulating layer IL may be positioned between the first substrate SUB1 and the second substrate SUB2. The insulating layer IL may include at least one selected from silicon oxide, silicon nitride, and silicon oxynitride. In another embodiment, the insulating layer IL may be omitted.

According to an embodiment, the first display area DA1 and the second display area DA2 that display images in different directions are driven by a single printed circuit board and a driving integrated circuit chip, such that the device may be simplified and provided with a thin thickness. In addition, since the coupling member is used to couple the first substrate and the second substrate, it is possible to provide a stable coupling state through a simple process.

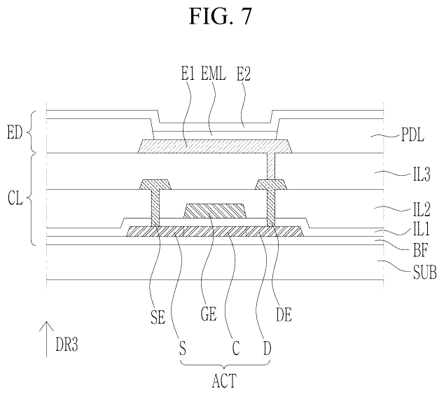

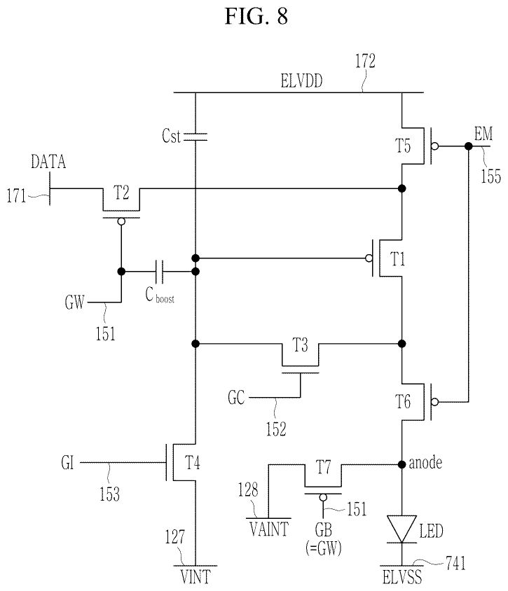

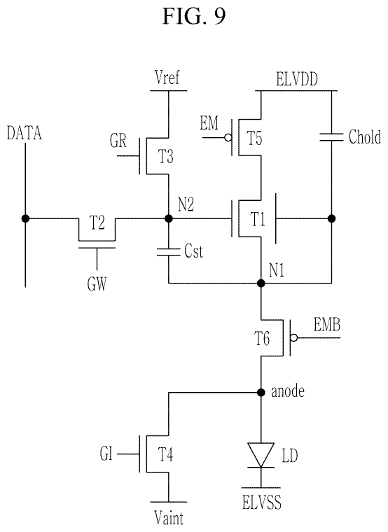

Hereinafter, a pixel according to an embodiment will be described with reference to FIGS. 7 and 9. FIG. 7 is a schematic cross-sectional view of a pixel according to an embodiment, FIG. 8 is a circuit diagram of a pixel according to an embodiment, and FIG. 9 is a circuit diagram of a pixel according to another embodiment.

At least one selected from the first circuit part CL1 and the second circuit part CL2 described above in FIGS. 4 and 5 may include a transistor including an oxide semiconductor. A transistor including an oxide semiconductor will hereinafter be described with reference to FIG. 7.

In an embodiment, a buffer layer BF may be disposed on the substrate SUB. In an embodiment where the first circuit part CL1 includes an oxide semiconductor transistor, the components described below may be mounted on the first substrate SUB1. In an embodiment where the second circuit part CL1 includes an oxide semiconductor transistor, the components described below may be mounted on the second substrate SUB2.

In an embodiment, the buffer layer BF may include silicon nitride (SiNₓ), silicon oxide (SiO₂), or silicon oxynitride. The buffer layer BF may planarize the substrate SUB and relieve the stress of a semiconductor layer ACT disposed on the buffer layer BF.

The semiconductor layer ACT is disposed on the buffer layer BF. The semiconductor layer ACT may include or be made of an oxide semiconductor. The semiconductor layer ACT may include a channel region C, a source region S, and a drain region D. In an embodiment where the semiconductor layer ACT includes or is made of an oxide semiconductor, a protective layer (not shown) may be additionally provided to protect the oxide semiconductor material, which is vulnerable to external environments such as high temperatures.

A gate insulating layer IL1 is disposed on the semiconductor layer ACT. The gate insulating layer IL1 may be a single layer or multiple layers (i.e., have a single layer structure or a multilayer structure) including at least one selected from silicon nitride (SiNₓ), silicon oxide (SiO₂), and silicon oxynitride.

A gate electrode GE is disposed on the gate insulating layer IL1. The gate electrode GE may be a multilayer in which metal layers including at least one selected from copper (Cu), a copper alloy, aluminum (Al), an aluminum alloy, molybdenum (Mo), and a molybdenum alloy are stacked.

An interlayer insulating layer IL2 is disposed on the gate electrode GE and the gate insulating layer IL1. The interlayer insulating layer IL2 may include silicon nitride (SiNₓ), silicon oxide (SiO₂), or silicon oxynitride. The interlayer insulating layer IL2 is provided with openings that expose the source region S and the drain region D, respectively.

The source electrode SE and the drain electrode DE are disposed on the interlayer insulating layer IL2. The source electrode SE and the drain electrode DE are connected to the source region S and the drain region D, respectively, of the semiconductor layer ACT through openings defined or formed in the interlayer insulating layer IL2.

A passivation layer IL3 is disposed on the interlayer insulating layer IL2, the source electrode SE, and the drain electrode DE. The passivation layer IL3 covers and planarizes the interlayer insulating layer IL2, the source electrode SE, and the drain electrode DE in a way such that a first electrode E1 may be disposed on the passivation layer IL3 without a step. The passivation layer IL3 may include or be made of an organic material such as polyacrylate resin, polyimide resin, or a laminated film of organic and inorganic materials.

The first electrode E1 is disposed on the passivation layer IL3. The first electrode E1 is electrically connected to the drain electrode DE through an opening defined in the passivation layer IL3.

A driving transistor including the gate electrode GE, the oxide semiconductor layer ACT, the source electrode SE, and the drain electrode DE is connected to each first electrode E1 and supplies a driving current to each light emitting device ED. In addition to the driving transistor shown in FIG. 7, the display device according to the embodiment may include a switching transistor (not shown) that is connected to a data line and transmits a data voltage in response to a scan signal, and a compensation transistor (not shown) that is connected to the driving transistor and compensates for a threshold voltage of the driving transistor in response to the scan signal. A circuit part CL according to an embodiment may include a semiconductor layer including an oxide semiconductor.

A partition wall PDL is disposed on the first electrode E1. The partition wall PDL includes an opening within which an emitting layer EML may be disposed. A second electrode E2 may be disposed on the emitting layer EML.

Here, the first electrode E1 may be an anode, which is a hole injection electrode, and the second electrode E2 may be a cathode, which is an electron injection electrode. However, the embodiment is not necessarily limited thereto, and depending on a driving method of the display device, the first electrode E1 may become a cathode and the second electrode E2 may become an anode.

According to an embodiment, the configuration from the buffer layer BF disposed on the substrate SUB to the passivation layer IL3 may be referred to as the circuit part CL. The circuit part CL may be applied to the first circuit part CL1 or the second circuit part CL2 described above.

Additionally, the configuration from the first electrode E1 to the second electrode E2 disposed on the circuit part CL may be referred to as a light emitting part ED. The light emitting part ED may be applied to the first light emitting part ED1 or the second light emitting part ED2 described above.

In embodiments, the first circuit part CL1 may include a plurality of transistors including oxide semiconductors, and the second circuit part CL2 may include a combination of transistors including oxide semiconductors and transistors including polycrystalline semiconductors.

Referring to FIG. 8, a pixel including an oxide transistor and a polycrystalline transistor will be described. The second circuit part CL2 according to an embodiment may include a pixel as in the embodiment of FIG. 8.

According to an embodiment, a pixel may include a plurality of transistors T1, T2, T3, T4, T5, T6, and T7, a maintenance capacitor Cst, a boost capacitor C_{boost} and a light emitting diode (LED) connected to a plurality of wirings 127, 128, 151, 152, 153, 155, 171, 172, and 741. Here, transistors and capacitors, excluding LEDs, configure or collectively define a pixel circuit part. In some embodiments, the boost capacitor C_{boost} may be omitted. In embodiments, an additional capacitor or an additional boost capacitor may be provided.

The plurality of wirings 127, 128, 151, 152, 153, 155, 171, 172, and 741 are connected to a pixel PX. The plurality of wirings include a first initialization voltage line 127, a second initialization voltage line 128, a first scan line 151, a second scan line 152, an initialization control line 153, a light emitting control line 155, a data line 171, a driving voltage line 172, and a common voltage line 741.

The first scan line 151 is connected to a scan driver (not shown) and transmits a first scan signal GW to the second transistor T2 and the seventh transistor T7. The second scan line 152 may be applied with a voltage of opposite polarity to the voltage applied to the first scan line 151 at the same timing as the signal of the first scan line 151. In an embodiment, for example, when a negative voltage is applied to the first scan line 151, a positive voltage may be applied to the second scan line 152. The second scan line 152 transmits a second scan signal GC to the third transistor T3. The initialization control line 153 transmits an initialization control signal GI to the fourth transistor T4. The light emitting control line 155 transmits a light emitting control signal EM to the fifth transistor T5 and the sixth transistor T6.

The data line 171 is a wiring that transmits a data voltage DATA generated from a data driver (not shown), and accordingly, the size of the light emitting current transmitted to the LED changes, thereby changing the luminance at which the LED emits light. The driving voltage line 172 applies a driving voltage ELVDD. The first initialization voltage line 127 transmits a first initialization voltage VINT, and the second initialization voltage line 128 transmits a second initialization voltage VAINT. The common voltage line 741 applies a common voltage ELVSS to the cathode of the LED. In an embodiment, the voltages applied to the driving voltage line 172, the first and second initialization voltage lines 127 and 128, and the common voltage line 741 may each be a constant voltage.

A driving transistor T1 (also referred to as a first transistor) is a p-type transistor and has a silicon semiconductor (hereinafter also referred to as a polycrystalline semiconductor or the first semiconductor) as the semiconductor layer thereof. The driving transistor T1 is a transistor that controls the amount of the light emitting current output to the anode of the LED based on the level of the voltage of the gate electrode of the driving transistor T1 (i.e., amount of the voltage stored in the maintenance capacitor Cst). Since the brightness of the LED is controlled by the amount of the light emitting current output to the anode of the LED, the light emitting luminance of the LED may be controlled based on the data voltage DATA applied to the pixel. To this end, the first electrode of the driving transistor T1 is connected to receive the driving voltage ELVDD and is connected to the driving voltage line 172 via the fifth transistor T5. Additionally, the first electrode of the driving transistor T1 is connected to the second electrode of the second transistor T2 and receives the data voltage DATA. In an embodiment, the second electrode of the driving transistor T1 outputs a light emitting current to the LED and is connected to the anode of the LED via the sixth transistor (T6; hereinafter also referred to as an output control transistor). Additionally, the second electrode of the driving transistor T1 is connected to the third transistor T3, to transmit the data voltage DATA applied to the first electrode to the third transistor T3. In an embodiment, the gate electrode of the driving transistor T1 is connected to one electrode of the maintenance capacitor Cst (hereinafter referred to as a “second maintenance electrode”). The other electrode of the maintenance capacitor Cst (hereinafter referred to as a “first maintenance electrode”) receives the driving voltage ELVDD. Therefore, the voltage of the gate electrode of the driving transistor T1 changes depending on the voltage stored in the maintenance capacitor Cst, and accordingly, the light emitting current output by the driving transistor T1 changes. The maintenance capacitor Cst serves to keep the voltage of the gate electrode of the driving transistor T1 constant during one frame. In an embodiment, the gate electrode of the driving transistor T1 may also be connected to the third transistor T3 so that the data voltage DATA applied to the first electrode of the driving transistor T1 may be transmitted to the gate electrode of the driving transistor T1 passing through the third transistor T3. In an embodiment, the gate electrode of the driving transistor T1 may also be connected to the fourth transistor T4 and be initialized after receiving the first initialization voltage VINT.

The second transistor T2 is a p-type transistor and has a silicon semiconductor as its semiconductor layer. The second transistor T2 is a transistor that receives data voltage DATA into the pixel. The gate electrode of the second transistor T2 is connected to the first scan line 151 and one electrode of the boost capacitor C_{boost} (hereinafter referred to as a “lower boost electrode”). The other electrode of the boost capacitor C_{boost} is connected to the gate electrode of the driving transistor T1 and the second maintenance electrode of the maintenance capacitor Cst. In an embodiment, the first electrode of the second transistor T2 is connected to the data line 171, and the second electrode of the second transistor T2 is connected to the first electrode of the driving transistor T1. When the second transistor T2 is turned on by a negative voltage of the first scan signal GW transmitted through the first scan line 151, the data voltage DATA transmitted through the data line 171 is transmitted to the first electrode of the driving transistor T1, and finally, the data voltage DATA is transmitted to the gate electrode of the driving transistor T1 and stored in the maintenance capacitor Cst.

The third transistor T3 is an n-type transistor and has an oxide semiconductor (hereinafter also referred to as a second semiconductor) as the semiconductor layer thereof. The third transistor T3 electrically connects the second electrode of the driving transistor T1 and the gate electrode of the driving transistor T1. As a result, the third transistor T3 allows the data voltage DATA to be compensated by the threshold voltage of the driving transistor T1 and stored in the second maintenance electrode of the maintenance capacitor Cst. The gate electrode of the third transistor T3 is connected to the second scan line 152, and the first electrode of the third transistor T3 is connected to the second electrode of the driving transistor T1. The second electrode of the third transistor T3 is connected to the second maintenance electrode of the maintenance capacitor Cst, the gate electrode of the driving transistor T1, and the other electrode of the boost capacitor C_{boost} (hereinafter referred to as an “upper boost electrode”). The third transistor T3 is turned on by a positive voltage of the second scan signal GC received through the second scan line 152, connects the gate electrode of the driving transistor T1 and the second electrode of the driving transistor T1, transmits the voltage applied to the gate electrode of the driving transistor T1 to the second maintenance electrode of the maintenance capacitor Cst, and stores the voltage in the maintenance capacitor Cst. At this time, the voltage stored in the maintenance capacitor Cst is the voltage of the gate electrode of the driving transistor T1 when the driving transistor T1 is turned off, and is stored in a compensated state with a threshold voltage Vth value of the driving transistor T1.

The fourth transistor T4 is an n-type transistor and has an oxide semiconductor as the semiconductor layer thereof. The fourth transistor T4 serves to initialize the gate electrode of the driving transistor T1 and the second maintenance electrode of the maintenance capacitor Cst. The gate electrode of the fourth transistor T4 is connected to the initialization control line 153, and the first electrode of the fourth transistor T4 is connected to the first initialization voltage line 127. The second electrode of the fourth transistor T4 is connected to the second electrode of the third transistor T3, the second maintenance electrode of the maintenance capacitor Cst, the gate electrode of the driving transistor T1, and the upper boost electrode of the boost capacitor C_{boost}. The fourth transistor T4 is turned on by a positive voltage among the initialization control signals GI received through the initialization control line 153, and at this time, the first initialization voltage VINT is transmitted to the gate electrode of the driving transistor T1, the second maintenance electrode of the maintenance capacitor Cst, and the upper boost electrode of the boost capacitor C_{boost} to perform initialization.

The fifth transistor T5 and the sixth transistor T6 are p-type transistors and have a silicon semiconductor as the semiconductor layer thereof.

The fifth transistor T5 serves to transmit the driving voltage ELVDD to the driving transistor T1. The gate electrode of the fifth transistor T5 is connected to the light emitting control line 155, the first electrode of the fifth transistor T5 is connected to the driving voltage line 172, and the second electrode of the fifth transistor T5 is connected to the first electrode of the driving transistor T1.

The sixth transistor T6 serves to transmit the light emitting current output from the driving transistor T1 to the LED. The gate electrode of the sixth transistor T6 is connected to the light emitting control line 155, the first electrode of the sixth transistor T6 is connected to the second electrode of the driving transistor T1, and the second electrode of the sixth transistor T6 is connected to the anode of the LED.

The seventh transistor T7 is a p-type or n-type transistor and may have a silicon semiconductor or an oxide semiconductor as the semiconductor layer thereof. In an embodiment, the seventh transistor T7 is a p-type transistor and includes a silicon semiconductor. The seventh transistor T7 serves to initialize the anode of the LED. The gate electrode of the seventh transistor T7 is connected to the first scan line 151, the first electrode of the seventh transistor T7 is connected to the anode of the LED, and the second electrode of the seventh transistor T7 is connected to the second initialization voltage line 128. Here, the gate electrode of the seventh transistor T7 is connected to the first scan line 151 of the previous pixel, and may not be connected to a same first scan line 151 as the gate electrode of the second transistor T2 of a same pixel PX, but may be connected to the same first scan line 151 as the gate electrode of the second transistor T2 of a previous pixel PX. When the seventh transistor T7 is turned on by the negative voltage of the first scan line 151, the second initialization voltage VAINT is applied to the anode of the LED for initialization. In an embodiment, the gate electrode of the seventh transistor T7 may be connected to a bypass control line through which a bypass signal GB is transmitted and controlled by a wiring from the first scan line 151. In embodiments, the second initialization voltage line 128 to which the second initialization voltage VAINT is applied may be identical to the first initialization voltage line 127 to which the first initialization voltage VINT is applied.

Although an embodiment where one pixel PX includes seven transistors T1 to T7 and two capacitors (the maintenance capacitor Cst and the boost capacitor C_{boost}) is described above, the disclosure is not limited thereto, and in another embodiment, the boost capacitor C_{boost} may be omitted. In another embodiment, an additional boost capacitor may be connected between the gate electrode of the third transistor T3 and the gate electrode of the driving transistor T1. Further, although an embodiment in which the third transistor T3 and the fourth transistor T4 are formed as n-type transistors is shown in FIG. 8, only one of the third transistor and the fourth transistor may be formed as an n-type transistor, or another transistor (e.g., the seventh transistor) may be formed as an n-type transistor in another embodiment.

In embodiments, as described above, the pixels of the display device include two types of semiconductors disposed in different layers, and the two types of semiconductors are a polycrystalline semiconductor (also referred to as the first semiconductor) and an oxide semiconductor (also referred to as the second semiconductor), respectively. The two types of semiconductors are each included in a transistor, and in this specification, a transistor including a polycrystalline semiconductor is referred to as a polycrystalline transistor, and a transistor including an oxide semiconductor is referred to as an oxide transistor. As such, one pixel may include a polycrystalline transistor and an oxide transistor, and the driving transistor T1 that provides driving current to the LED is a polycrystalline transistor. All transistors except for the driving transistor T1 are also referred to as switching transistors, and the switching transistors may be divided into polycrystalline switching transistors and oxide switching transistors.

Referring to FIG. 9 below, a pixel including an oxide transistor and a polycrystalline transistor will be described. The second circuit part CL2 according to an embodiment may include a pixel as in the embodiment of FIG. 9.

Referring to FIG. 9, in an embodiment a pixel may include a first transistor T1 (or a driving transistor), a second transistor T2, and a first capacitor Cst (or a storage capacitor). In such an embodiment, the pixel may further include the third transistor T3, the fourth transistor T4, the fifth transistor T5, the sixth transistor T6, and a second capacitor C_{hold} (or a hold capacitor).

The first transistor T1 may be electrically connected between a first power line for providing a first power voltage ELVDD and a second node N2. In an embodiment, for example, the first electrode of the first transistor T1 may be connected to the first power line for providing the first power voltage ELVDD via the fifth transistor T5, and the second electrode of the first transistor T1 may be connected to the second node N2. The gate electrode of the first transistor T1 may be connected to the first node N1. Additionally, the first transistor T1 further includes a lower electrode (or a second gate electrode) corresponding to the gate electrode, and the lower electrode may be connected to the second node N2. The first transistor T1 may supply driving current to the light emitting device LD, or control the amount of driving current flowing to the light emitting device LD from the first power line that provides the first power voltage ELVDD. In an embodiment, for example, the first transistor T1 may supply a driving current corresponding to the voltage of the first node N1 to the light emitting device LD.

The second transistor T2 may be electrically connected between a data line for providing the data voltage DATA and the first node N1. The gate electrode of the second transistor T2 may be turned on in response to the first scan signal GW of the first scan line. When the second transistor T2 is turned on, the data signal DATA of the data line may be transmitted to the first node N1.

The third transistor T3 may be electrically connected between a reference power line for providing a reference power voltage Vref and the first node N1. The gate electrode of the third transistor T3 may be connected to the second scan line and receive the second scan signal GR. When the third transistor T3 is turned on, the reference power voltage Vref may be transmitted to the first node N1.

The fourth transistor T4 may be electrically connected between the anode electrode of the light emitting device LD and the second initialization power line that applies the second initialization voltage VAINT. The gate electrode of the fourth transistor T4 may be connected to a third scan line that transmits the third scan signal GI. The fourth transistor T4 may be turned on in response to the third scan signal GI. When the fourth transistor T4 is turned on, the second initialization voltage VAINT may be transmitted to the anode electrode of the light emitting device LD.

The fifth transistor T5 may be electrically connected between the first power line that applies the first power voltage ELVDD and the first transistor T1. The gate electrode of the fifth transistor T5 may be connected to a first light emitting control line that applies a first light emitting control signal EM.

The sixth transistor T6 may be electrically connected between the second node N2 and the anode of the light emitting device LD. The gate electrode of the sixth transistor T6 may be connected to a second light emitting control line that applies a second light emitting control signal EMB.

The first capacitor Cst may be formed or electrically connected between the first node N1 and the second node N2. A voltage corresponding to the data voltage DATA may be stored in the first capacitor Cst.

The second capacitor Chold may be formed or electrically connected between the first power line that applies the first power voltage ELVDD and the second node N2. The second capacitor Chold may stabilize the voltage of the second node N2.

The light emitting device LD may be electrically connected between the sixth transistor T6 and a second power line to which a second power voltage ELVSS is applied. In an embodiment, for example, the light emitting device LD may be forward-connected between the second node N2 and the second power line. When a driving current is supplied from the first transistor T1, the light emitting device LD may emit light with a luminance corresponding to the driving current.

In an embodiment, the light emitting device LD may include an organic light emitting diode. In another embodiment, the light emitting device LD may include at least one inorganic light emitting diode. The type, size, and/or number of light emitting devices LDs may vary depending on embodiments.

At least one selected from the first to sixth transistors T1 to T6 may be changed to a p-type transistor. Depending on the type of each transistor, the voltage levels of driving signals for controlling the operation of the transistor may be set.

In an embodiment, at least one selected from the first to sixth transistors T1 to T6 may include an oxide semiconductor. In an embodiment, for example, the first transistor T1, the second transistor T2, the third transistor T3, and the fourth transistor T4 may be oxide semiconductor transistors including oxide semiconductors.

In embodiments, the first circuit part CL1 described in FIGS. 4 and 5 may include oxide transistors, and the second circuit part CL2 may also include oxide transistors. At this time, the first driver GD1 electrically connected to the first circuit part CL1 and the second driver GD2 electrically connected to the second circuit part CL2 may also include oxide transistors.

Alternatively, the first circuit part CL1 may include oxide transistors, and the second circuit part CL2 may include a combination of oxide transistors and polycrystalline transistors. The second circuit part CL2 may include a pixel as described in FIG. 8 or FIG. 9, in embodiments. In an embodiment, the first driver GD1 electrically connected to the first circuit part CL1 may be configured by an oxide transistor. In such an embodiment, the second driver GD2 electrically connected to the second circuit part CL2 may be configured by a combination of oxide transistors and polycrystalline transistors. In such an embodiment, where the circuit parts CL1 and CL2 and the drivers GD1 and GD2 include a same type of transistors, power consumption may be reduced.

A display device according to an embodiment may be applied to various electronic devices. An electronic device according to an embodiment may include the display device, and may further include modules or devices having additional functions other than the display device.

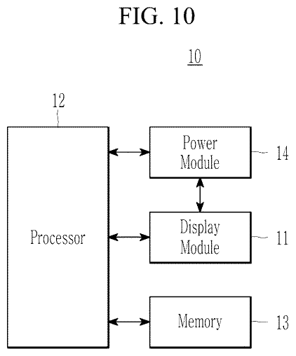

FIG. 10 is a block diagram of an electronic device according to an embodiment. Referring to FIG. 1, the electronic device 10 according to an embodiment may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 15 may store data information necessary for operations of the processor 12 or the display module 11. When the processor 12 executes an application stored in the memory 15, video data signals and/or input control signals are transmitted to the display module 11, and the display module 11 can process the received signals to output video information through the display screen.

The power module 14 may include a power supply module such as a power adapter or battery device, and a power conversion module that converts the power supplied by the power supply module to generate the power necessary for the operation of the electronic device 10.

At least one of components of the electronic device 11 may be included within the display device according to the above-described embodiments.

Additionally, some of the individual modules that are functionally included within a single module may be incorporated into the display device, while others may be provided separately from the display device. For example, the display device may include the display module 11, while the processor 12, memory 13, and power module 14 may be provided in a form of other devices within the electronic device 11 that are not part of the display device.

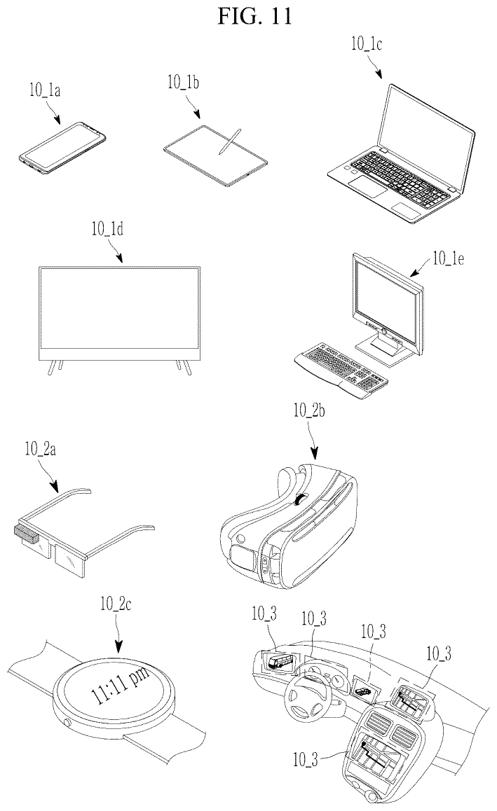

FIG. 11 shows schematic diagrams of electronic devices according to various embodiments.

Referring to FIG. 11, various electronic devices with the display device according to the embodiments may include not only image display electronic devices such as smartphones 10_1a, tablet PCs 10_1b, laptops 10_1c, TVs 10_1d, desktop monitors 10_1e, but also wearable electronic devices with display modules such as smart glasses 10_2a, head-mounted displays 10_2b, smart watches 10_2c, as well as automotive electronic devices with display modules 10_3 such as those placed on car dashboards, center fascias, CID (Center Information Display), room mirror displays, and so on.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a first substrate;
a first circuit part disposed on a front surface of the first substrate;
a first light emitting part electrically connected to the first circuit part;
a second substrate overlapping the first substrate and disposed on a rear surface of the first substrate;
a second circuit part disposed on a rear surface of the second substrate;
a second light emitting part electrically connected to the second circuit part;
a printed circuit board electrically connected to the first circuit part and the second circuit part; and
a driving integrated circuit chip disposed on the printed circuit board.

2. The display device of claim 1, further comprising:
a first driver disposed on the first substrate; and
a second driver disposed on the second substrate,
wherein the first driver is electrically connected to a first end of the printed circuit board, and the second driver is electrically connected to a second end of the printed circuit board.

3. The display device of claim 2, wherein
the display device comprises a first display area including the first circuit part and the first light emitting part, and
the first display area is foldable based on a folding axis extending along a predetermined direction.

4. The display device of claim 3, wherein
the display device is in-folded based on the folding axis, and
a second display area including the second circuit part and the second light emitting part is disposed outward when the display device is in an in-folded state.

5. The display device of claim 4, wherein
a size of the second display area is smaller than a size of the first display area.

6. The display device of claim 4, wherein
the first circuit part includes an oxide semiconductor.

7. The display device of claim 4, wherein
the second circuit part includes an oxide semiconductor.

8. The display device of claim 4, wherein
the second circuit part comprises a plurality of transistors,
and at least one of the plurality of transistors include an oxide semiconductor, and a remainder of the plurality of transistors include a polycrystalline semiconductor.

9. The display device of claim 4, wherein
the first driver includes an oxide semiconductor.

10. The display device of claim 9, wherein
the second driver includes an oxide semiconductor and a polycrystalline semiconductor.

11. The display device of claim 1, wherein
a first groove is defined on the rear surface of the first substrate,
a second groove is defined on a front surface of the second substrate to overlap the first groove,
and the display device further comprises a coupling member disposed in the first groove and the second groove.

12. The display device of claim 11, wherein
the coupling member includes a same material as at least one selected from the first substrate and the second substrate.

13. The display device of claim 11, further comprising
an insulating layer disposed between the first substrate and the second substrate.

14. A display device comprising:
a first substrate;
a first circuit part disposed on a front surface of the first substrate;
a first light emitting part electrically connected to the first circuit part;
a second substrate overlapping the first substrate and disposed on a rear surface of the first substrate;
a second circuit part disposed on a rear surface of the second substrate;
a second light emitting part electrically connected to the second circuit part;
a printed circuit board electrically connected to the first circuit part and the second circuit part; and
a driving integrated circuit chip disposed on the printed circuit board;
wherein the first circuit part and the first light emitting part define a first display area,
the second circuit part and the second light emitting part define a second display area,
and the first display area is foldable.

15. The display device of claim 14, wherein
a first end of the printed circuit board is electrically connected to the first circuit part, and
a second end of the printed circuit board is electrically connected to the second circuit part.

16. The display device of claim 14, wherein
the first circuit part includes an oxide semiconductor.

17. The display device of claim 14, wherein
the second circuit part comprises a plurality of transistors,
and at least one of the plurality of transistors include an oxide semiconductor, and the remainder of the plurality of transistors include a polycrystalline semiconductor.

18. The display device of claim 14, wherein
a first groove is defined on the rear surface of the first substrate,
a second groove is defined on a front surface of the second substrate to overlap the first groove,
and the display device further comprises a coupling member disposed in the first groove and the second groove.

19. The display device of claim 18, wherein
the coupling member includes a same material as at least one selected from the first substrate and the second substrate.

20. The display device of claim 18, wherein
the coupling member comprises polyimide.

21. An electronic device comprising the display device of claim 1.

22. An electronic device comprising the display device of claim 14.
